(19) United States
(12) Patent Application Publication
(10) Pub. No.: US 2008/0083927 A1
(43) Pub. Date: Apr. 10, 2008

(54) DISPLAY DEVICE AND METHOD OF MANUFACTURING THE SAME

(75) Inventors: Atsunori Nishiura, Tokyo (JP); Toru Takeguchi, Tokyo (JP); Takuji Imamura, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Tokyo (JP)

(21) Appl. No.: 11/866,132

(22) Filed: Oct. 2, 2007

(30) Foreign Application Priority Data
Oct. 4, 2006 (JP) 2006-273106
Jun. 18, 2007 (JP) 2007-160651

(51) Int. Cl. H01L 29/04; H01L 21/00

(52) U.S. Cl. 257/72; 438/34; 257/E33.001; 257/E29.003

(57) ABSTRACT

A display device includes a substrate, a gate insulating film provided over the substrate and disposed between a semiconductor layer and a first conductive layer including a capacitor electrode and a gate electrode, an interlayer insulating film formed over the semiconductor layer, the first conductive layer and the gate insulating film, a second conductive layer having a signal line formed over the interlayer insulating film, a protective film formed over the interlayer insulating film and the second conductive layer and a pixel electrode layer formed over the protective film. The semiconductor layer and the second conductive layer are connected via the pixel electrode layer by the pixel electrode layer penetrating the protective film to reach the second conductive layer and also penetrating the protective film, the interlayer insulating film and the gate insulating film to reach the semiconductor layer.

### BACKGROUND OF THE INVENTION

1. Field of the Invention

The present invention relates to a display device and a method of manufacturing the same.

2. Description of Related Art

There are display devices such as an active matrix liquid crystal display and an organic EL (electroluminescence) that uses a thin film transistor (TFT) as a pixel switching device. In these display devices, a polycrystalline silicon thin film transistor using polycrystalline silicon as a channel active layer of a TFT has high mobility. Moreover, in case of a polycrystalline silicon TFT is used as a pixel switching device, it is possible to make a display device high in detail. And a polycrystalline silicon can be incorporated to the peripheral circuit part for driving the pixel switching device.

In related arts, to a polycrystalline silicon film used as an active layer of a TFT and a conducting film used as a gate electrode and a capacitor electrode, conductivity is established through a source drain metal which is located in the upper part and used as a signal line (For example, see Japanese Unexamined Patent Application Publication No. 2001-168343). In this case, it is common to form a contact hole to the polycrystalline silicon film, the gate electrode and the capacitor electrode before forming a signal line and to form a signal line after that.

It is also common to dispose an insulating film (also referred to as a passivation film) over the signal line. Moreover, a through-hole must be formed to the insulating film over the signal line for conductivity to the signal line (see FIG. 12).

Moreover, in the TFT array part including a TFT of a display unit according to a related art, a contact hole is included under a signal line. In case of a terminal area is formed simultaneously with a TFT array part, a contact hole is formed in each of an interlayer insulating film and a protective film also in the terminal area. The terminal area connects a circuit and a display area which are formed over a substrate having a TFT. Furthermore, a terminal wiring needed to be connected with a pixel electrode layer via the signal line (see FIGS. 13A and 13B).

In the manufacturing method of a related art, the contact hole must be formed in the portion to be under the signal line before forming the signal line in order for the signal line as a second line to establish conductivity with a gate electrode and a capacitor electrode as a first line thereunder or with a polysilicon film as a semiconductor layer. Furthermore, generally as an insulating film (also referred to as a passivation film) is disposed over the signal line after forming the signal line, a through hole must be formed to establish conductivity with the top layer. Therefore, there are many mask processes required and there has been a problem in the cost. Moreover, as for the portion where conductivity of the signal line, the gate electrode and the capacitor electrode is established via the contact hole, conductive layers are overlapped. Accordingly, there has been a problem that unevenness of the pixel electrode surface which is the topmost part becomes large. In this case, display quality deteriorates. Thus, in a liquid crystal display of a related art, there is a problem that productivity is low and display quality deteriorates.

Furthermore, the terminal area of the TFT substrate is formed simultaneously with the display area of a substrate where TFT is formed. For this reason, in order to connect the pixel electrode layer with the terminal wiring formed in the same layer as the gate electrode, firstly it is necessary to connect the pixel electrode layer with the signal line via the contact hole and to connect the signal line and the terminal wiring via the contact hole. That is, the contact hole could not be formed collectively but there were many manufacture processes of the TFT substrate. Moreover, the substrate area for providing the contact hole formed in the insulating film between the signal line and the terminal wiring and the through hole formed in the insulating film between the signal line and the pixel electrode is needed. That is, there has been a problem that the area of the terminal area increases.

The present invention seeks to solve one or more of the above problems, or to improve upon those problems at least in part and aims to provide a display device with high productivity and display quality and a method of manufacturing the same.

### SUMMARY OF THE INVENTION

According to an aspect of the present invention, there is provided a display device includes a substrate, a gate insulating film provided over the substrate and disposed between a semiconductor layer and a first conductive layer including a capacitor electrode and a gate electrode, an interlayer insulating film formed over the semiconductor layer, the first conductive layer and the gate insulating film, a second conductive layer having a signal line formed over the interlayer insulating film, a protective film formed over the interlayer insulating film and the second conductive layer and a pixel electrode layer formed over the protective film. The semiconductor layer and the second conductive layer are connected via the pixel electrode layer by the pixel electrode layer penetrating the protective film to reach the second conductive layer and also penetrating the protective film, the interlayer insulating film and the gate insulating film to reach the semiconductor layer.

The present invention is able to provide a display device with high productivity and display quality and a method of manufacturing the same.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing the structure of a TFT substrate according to a first embodiment;

FIG. 2A is a cross-sectional diagram showing the structure of a TFT part, a conversion part and a protection circuit part of the TFT substrate according to the first embodiment;

FIG. 2B is a plan view showing the structure of a protection circuit of the TFT substrate according to the first embodiment;

FIG. 3 is a cross-sectional diagram showing the structure of a TFT substrate according to a second embodiment;

FIG. 4 is a cross-sectional diagram showing the structure of a TFT substrate according to a third embodiment.

FIG. 5 is a cross-sectional diagram showing the structure of a TFT substrate according to a fourth embodiment;

FIG. 6 is a cross-sectional diagram showing the structure of a TFT substrate according to a fifth embodiment;

FIG. 7 is a cross-sectional diagram showing the structure of a TFT substrate according to a sixth embodiment;

FIG. 8 is a cross-sectional diagram showing the structure of a TFT substrate according to a seventh embodiment;

FIG. 9A is a cross-sectional diagram showing the structure of a terminal area of a TFT substrate according to a eighth embodiment;

FIG. 9B is a plan view showing the structure of a terminal area of the TFT substrate according to the eighth embodiment;

FIG. 10 is a cross-sectional diagram showing the structure of a terminal area of a TFT substrate according to a ninth embodiment;

FIG. 11 is a cross-sectional diagram showing the structure of a terminal area of a TFT substrate according to a tenth embodiment;

FIG. 12 is a cross-sectional diagram showing the structure of a TFT substrate according to a related art;

FIG. 13A is a cross-sectional diagram showing the structure of a TFT substrate according to a related art; and

FIG. 13B is a plan view showing the structure of a TFT substrate according to a related art.

### DETAILED DESCRIPTION OF REFERRED EMBODIMENTS

Embodiments that the present invention can be incorporated are described hereinafter. The following explanation is concerning the embodiments of the present invention and the present invention is not limited to the following embodiments.

### First Embodiment

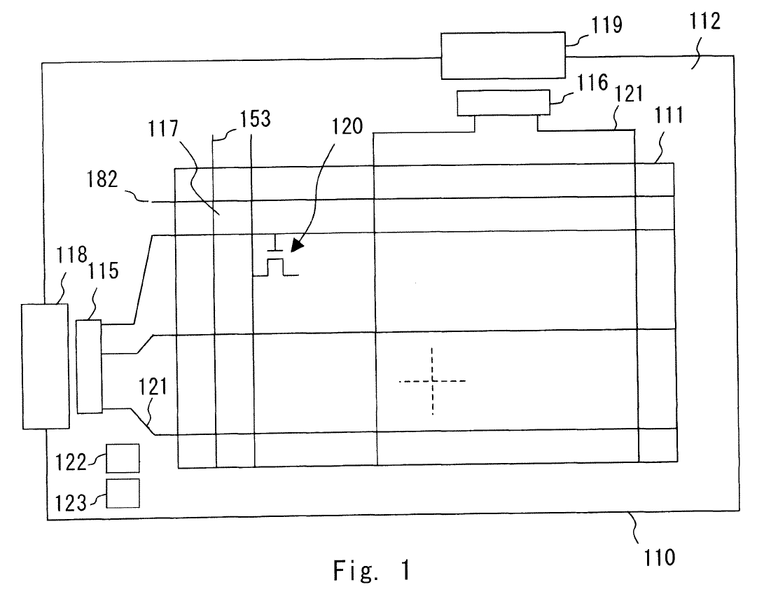

Firstly, an active matrix display device that a TFT substrate according to the present invention is incorporated is explained with reference to FIG. 1. FIG. 1 is a front view showing the structure of the TFT substrate used for a display device. Although the display device according to the present invention is explained with a liquid crystal display as an example, it is only illustrative and a flat panel display such as an organic EL display device etc. can be used.

The liquid crystal display according to the present invention includes a TFT substrate 110. The TFT substrate 110 is a TFT array substrate, for example. The TFT substrate 110 includes a display area 111 and a frame area 112 provided to surround a display area 111. A frame area 112 provided to surround a display area 111 is included in the TFT substrate 110. In this display area 111, a plurality of gate lines (scanning signal line) 182 and a plurality of source lines (display signal line) 153 are formed that supply a signal to a TFT 120 described later. The plurality of the gate lines 182 are provided in parallel. Similarly, the plurality of source lines 153 are provided in parallel. The gate lines 182 and the source lines 153 are formed to cross each other. The gate lines 182 and the source lines 153 are orthogonal to each other. And the area surrounded by adjacent gate line 182 and the source line 153 is to be a pixel 117. Therefore, in the TFT substrate 110, the pixels 117 are arranged in matrix.

Furthermore, a scanning signal drive circuit 115 and a display signal drive circuit 116 are provided in the frame area 112 of the TFT substrate 110. The gate lines 182 are extended from the display area 111 to the frame area 112. In the frame area 112 which is an end of the TFT substrate 110, the gate lines 182 are connected to the scanning signal drive circuit 115 via routing lines 121. A conversion part 122 for changing wiring layer provided in the routing lines 121. Likewise, the source lines 153 are extended from the display area 111 to the frame area 112. In the frame area 112 which is an end of the TFT substrate 110, the source lines 153 are connected to the display signal drive circuit 116 via the routing lines 121. The conversion part 122 for changing wiring layer is provided in the routing line 121. An external wiring 118 is connected near the scanning signal drive circuit 115. Moreover, an external wiring 119 is connected near the display signal drive circuit 116. The external wirings 118 and 119 are wiring substrates such as FPC (Flexible Printed Circuit), for example. And in the frame area 112 of the TFT substrate 110, a protection circuit 123 is included for protecting each wiring from dielectric breakdown between the gate lines 182 and the source lines 153 or between the routing lines 121 in different layers. Details are described later.

Various external signals are supplied to the scanning signal drive circuit 115 and the display signal drive circuit 116 via the external wirings 118 and 119. The scanning signal drive circuit 115 supplies a gate signal (scanning signal) to the gate line 182 based on a control signal from the outside. The gate lines 182 are selected sequentially according to the gate signal. The display signal drive circuit 116 supplies a display signal to the source lines 153 based on the control signal and display data from the outside. This enables to supply a display voltage according to the display data to each pixel 117.

At least one TFT 120 is formed in the pixel 117. The TFT 120 is disposed near the intersection of the source line 153 and the gate line 182. For example, the TFT 120 supplies a display voltage to a pixel electrode. That is, by a gate signal from the gate line 182, the TFT 120 which is a switching device is turned on. Accordingly, the display voltage is applied to the pixel electrode connected to a drain electrode of the TFT from the source line 153. Then an electric field corresponding to the display voltage is generated between the pixel electrode and an opposing electrode. Note that an alignment film (not shown) is formed to the surface of the TFT substrate 110.

Furthermore, an opposing substrate is disposed to oppose the TFT substrate 110. The opposing substrate is for example a color filter substrate and is disposed to the visible side. A color filter, a black matrix (BM), an opposing electrode, an alignment film or the like are formed to the opposing substrate. Note that the opposing electrode may be disposed to the TFT substrate 110 side. Then, a liquid crystal layer is held between the TFT substrate 110 and the opposing substrate. That is, a liquid crystal is filled between the TFT substrate 110 and the opposing substrate. Moreover, a polarizing plate, a retardation film or the like are provided to the surface outside the TFT substrate 110 and the opposing substrate. Moreover, a backlight unit or the like is placed to the non-visible side of the liquid crystal display panel.

The liquid crystal is driven by the electric field between the pixel electrode and the opposing electrode. That is, the alignment direction of the liquid crystal between the substrates changes. Then, the polarization state of light passing through the liquid crystal layer changes. That is, the light passed through the polarization plate to become a linear polarization changes its polarization state by the liquid crystal layer. To be more specific, the light from the backlight unit turns into a linear polarization with the polarization plate by the side of an array substrate. Then the polarization state changes by the linear polarization passing through the liquid crystal layer.

Therefore, the amount of light passing through the polarizing plate on the opposing substrate changes according to the polarization state. Specifically, among the transmitted light transmitting the liquid crystal display panel from the backlight unit, the amount of light passing through the polarizing plate on the visible side changes. The alignment direction of the liquid crystal changes according to the display voltage applied. Accordingly, by controlling the display voltage, the amount of light passing through the polarizing plate on the visible side can be changed. That is, by changing the display voltage for each pixel, a desired image can be displayed.

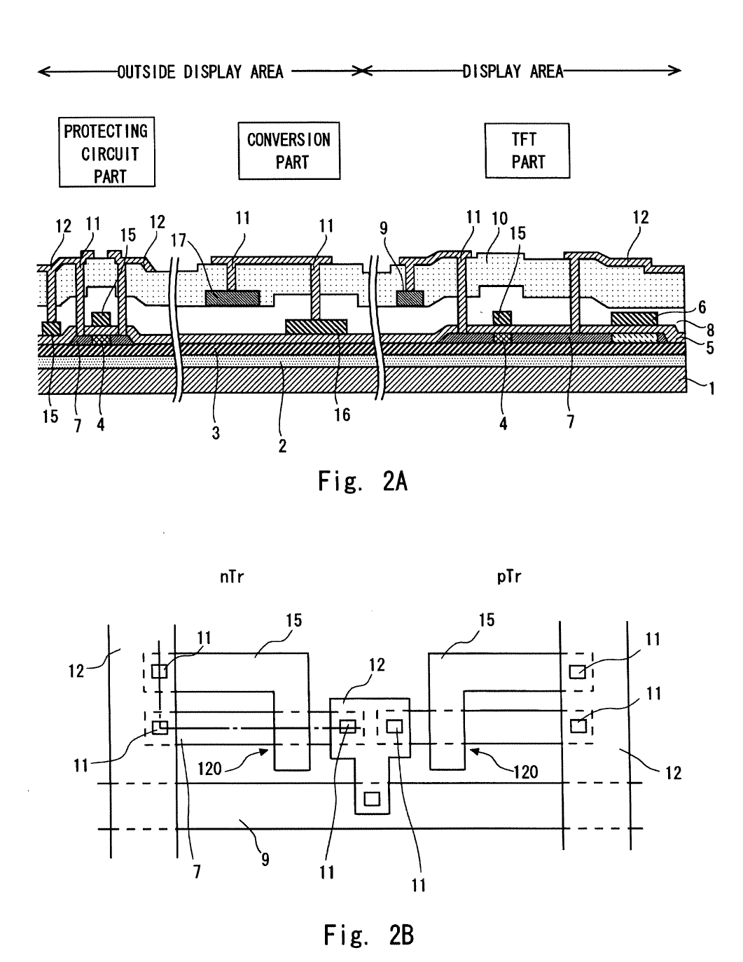

Next, the structure of the TFT 120 provided to the TFT substrate 110 and a manufacturing process are explained with reference to FIGS. 2A and 2B. The cross-sectional diagram of the TFT part, a conversion part and a protection circuit part of the display device according to the first embodiment is shown in FIG. 2A. The right area of FIG. 2A shows the TFT part formed in the display area and the left area shows the conversion part and the protection circuit part formed outside the display area. Moreover, the plan view of the protection circuit formed in the frame area over the substrate of the display device according to the first embodiment is shown in FIG. 2B. Note that the cross-sectional diagram taken along the dashed dotted line shown in FIG. 2B is a cross-sectional diagram shown in FIG. 2A. Firstly, the display device of this embodiment is explained, mainly with reference to FIG. 2A. In this embodiment, it is explained as a top gate type TFT 120. A foundation film to be an insulating film is provided over a glass substrate 1. Firstly, 50 nm of a silicon nitride film 2 which is a foundation film is formed by plasma CVD method. This silicon nitride film 2 is formed in order to prevent Na (sodium) contamination from the glass substrate 1. Then, 200 nm of a silicon oxide film 3 is formed by plasma CVD method. This silicon oxide film 3 takes a supporting role at the time of crystallizing an amorphous silicon, which is performed later. The silicon nitride film 2 and the silicon oxide film 3 are formed substantially all over the substrate 1. Note that the foundation film may be formed with materials other than the silicon nitride film 2 or silicon oxide film 3. Furthermore, the foundation film may be formed to be a single layer. By forming the foundation film in this way, the characteristics of the TFT can be stabilized.

Next, 50 nm of an amorphous silicon is formed by plasma CVD. A heat treatment is performed to reduce the hydrogen concentration in the amorphous silicon. Then, the amorphous silicon is crystallized by laser annealing method to be a polysilicon film 4. For the laser annealing method, there are excimer laser annealing method and YAG laser annealing method or the like, but it is not limited to these. To be more specific, the amorphous silicon is melted by laser irradiation and then cooled and solidified to be polysilicon. Then, a resist pattern is formed by photolithography. A dry etching is performed with the resist pattern interposed therebetween to form the polysilicon film 4 for forming a transistor in a desired shape. Then, the resist is removed. The polysilicon film 4 is formed to shape an island over the silicon oxide film 3. This enables to form the polysilicon film 4 to be a semiconductor layer in the portion to form a TFT.

Next, a gate insulating film 5 is formed over the polysilicon film 4 by plasma CVD method. As a gate insulating film 5, a silicon oxide film with 80 nm thickness can be used, for example. This enables to cover the polysilicon film 4 by the gate insulating film 5. Next, a resist pattern is formed by photolithography and impurities are selectively introduced into the area to be a capacitor lower part electrode of the semiconductor layer. Then the conductivity of the semiconductor layer directly under a capacitor electrode 6 improves, which is formed later, and the voltage dependency of the capacitor can be reduced.

Subsequently, a metal thin film for forming a first conductive layer including a gate electrode 15, a capacitor electrode 6 and a first routing line 16 is formed by sputtering method. As the metal thin film, Al, Cr, Mo, Ti, W, etc. or an alloy of these metals added with a small amount of other material can be used, for example. After forming the metal thin film for forming the gate electrode 15, the capacitor electrode 6 and the first routing line 16, a resist pattern is formed by photolithography. Then, a metal thin film is patterned in a desired shape by an etchant. In this way, the gate electrode 15, the capacitor electrode 6 and the first routing line 16 provided outside the display area are formed. The gate electrode 15 is formed over the channel region of the polysilicon film 4. The capacitor electrode 6 is directly formed over the gate insulating film 5. Then, the resist over the gate electrode 15 and the capacitor electrode 6 is removed. This gate electrode 15 is the gate line 182 or the like, for example.

Next, impurities are introduced into the polysilicon film 4 by using the gate electrode 15 and the capacitor electrode 6 as a mask. Then the impurities are introduced into a source/drain region 7 disposed to the both sides of the channel region. Here, ion injection method, ion doping method or the like can be used. Note that it may be LDD (Lightly Doped Drain) structure for the improvement in reliability. A TFT is formed in this way.

Then, a silicon oxide film to be an interlayer insulating film 8 is formed over the gate insulating film 5 by plasma CVD method. Thus, the capacitor electrode 6 and the polysilicon film 4 are covered with the interlayer insulating film 8. The interlayer insulating film 8 is a 500 nm thickness silicon oxide film to which TEOS and O₂ were made to react. Note that although an example of 500 nm was given as film thickness of the interlayer insulating film 8, it is not limited to this. Moreover, the interlayer insulating film 8 is not limited to a silicon oxide film but may be a silicon nitride film, an organic film, etc.

Subsequently, in order to activate P (phosphorus) and B (boron) which were introduced into the polysilicon film 4, a heat treatment is performed. The heat treatment shall be 400 degrees Celsius for 1 hour in a nitrogen atmosphere.

Next, a metal thin film for forming a second conductive layer which is made up of a source drain metal and including a signal line 9 and a second routing line 17 is formed by sputtering method. The signal line 9 is a metal material such as Al, Cr, Mo, Ti and W or an alloy material. Here, it is a laminated structure of Mo alloy/Al alloy/Mo alloy, and film thickness is 100 nm/300 nm/100 nm, respectively. Then, a resist pattern is formed by photolithography and the signal line 9 is patterned in a desired shape by dry etching method.

In this way, a plurality of the signal lines 9 and the second routing line 17 provided outside the display area are formed over the interlayer insulating film 8. This signal lines 9 are the source lines 153, for example. The signal lines 9 and the second routing line 17 are not formed over contact holes 11 connected to the first routing line 16 and contact holes 11 connected to the source/drain region 7 of the polysilicon film 4. The formation process of the contact holes 11 is described later. This signal line 9 and the second routing line 17 are formed before the forming process of the contact hole of the interlayer insulating film 8. That is, after forming the interlayer insulating film 8, before patterning the contact hole 11 formed to the interlayer insulating film 8 or the gate insulating film 5, the signal line 9 and the second routing line 17 are formed.

Then, 300 nm of a silicon nitride film to be a protective film 10 is formed by plasma CVD method. Subsequently, a heat treatment is performed for damage recovery. The heat treatment shall be 250 degrees Celsius for 1 hour in an atmosphere. The protective film 10 is not limited to a silicon nitride film but may be an insulating film such as a silicon oxide film and an organic film.

After forming the protective film 10, the contact hole 11 which penetrates the protective film 10 and reaches the signal line 9 and the second routing line 17 is formed. Moreover, in this process, the contact hole 11 which penetrates the protective film 10 and the interlayer insulating film 8 to reach the first routing line 16 is formed. Furthermore, in this process, the contact hole 11 which penetrates the protective film 10, the interlayer insulating film 8 and the gate insulating film 5 to reach the source/drain region of the polysilicon film 4 is formed. Specifically, a resist pattern is formed over the protective film 10 by the photolithography method. Then, the protective film 10, the interlayer insulating film 8 and the gate insulating film 5 are dry etched in turn. In this way, the contact holes 11 are formed. With one photomask, the contact holes 11 which penetrate the protective film 10, the interlayer insulating film 8 and the gate insulating film 5 can be formed.

After forming the contact holes 11, a pixel electrode layer 12 is formed. Then, the pixel electrode layer 12 is patterned by photolithography method etc. The pixel electrode layer 12 can be formed with a transparent conducting film such as an ITO film. Or the pixel electrode layer 12 may be formed with metals such as Cr, Mo, Al, Ta and Ti or an alloy which uses these metals as the main constituent. A pixel electrode applied with a driving voltage (display voltage) for driving a liquid crystal is included in this pixel electrode layer 12. For example, in the case of a liquid crystal display, the pixel electrode is connected with a drain of a TFT. This pixel electrode layer 12 is laid under the contact hole 11. In the TFT part in the display area, the source region and the signal line 9 of the polysilicon film 4 are physically and electrically connected via the pixel electrode layer 12 laid under the contact hole 11. Moreover, the gate line and the source line which are formed in the display area over the TFT substrate 110 are connected with the driving circuit via a routing line. The routing line includes the first routing line 16 and the second routing line 17 and the conversion part 122 for changing wiring layer is provided. Then, in the conversion part 122, the first routing line 16 and the second routing line 17 are physically and electrically connected via the pixel electrode layer 12 laid under the contact hole 11. Between the polysilicon film 4 and the signal line 9, there is no direct connection mutually and there is an indirect electric connection only via the pixel electrode layer 12. Similarly, between the first routing line 16 and the second routing line 17, there is no direct connection mutually and there is an indirect electric connection only via the pixel electrode layer 12.

That is, in the conversion part 122 outside the display area, the second routing line 17 and the first routing line 16 formed in a gate layer are connected via the pixel electrode layer 12. Moreover, in the TFT part in the display area, the signal line 9 and the polysilicon film 4 are connected via the pixel electrode layer 12. Thus, the signal line 9 is connected with the polysilicon film 4 of the TFT via the pixel electrode layer 12. Therefore, the number of mask process for forming the contact hole in the interlayer insulating film 8 can be less than in a related art and the flatness of the pixel surface improves.

That is, since the contact hole is not formed directly under the signal line 9 and the second routing line 17, the photolithography process for patterning the interlayer insulating film 8 before forming the signal line 9 can be skipped after forming the interlayer insulating film 8. Accordingly, the number of masks used for the photolithography process can be reduced. Thus the productivity can be improved.

In this case, a signal from the signal line 9 is supplied to the polysilicon film 4 via the pixel electrode layer 12. Moreover, a signal can be supplied directly to the pixel electrode from the polysilicon film 4. Thus, no signal line layers are directly connected with the polysilicon film 4 or the gate layer.

Note that the interlayer insulating film 8 is not removed directly under the signal line 9. Therefore, the interlayer insulating film 8 is always formed directly under the signal line layer. In other words, all the signal line layers are disposed over the area in which the interlayer insulating film 8 is formed. That is, in all the areas in which the signal line layers are formed, the interlayer insulating film 8 is disposed directly under the signal line layer. Furthermore, it is possible to have the structure where the signal line layer and the contact hole connected to the signal line layer are not disposed directly under the pixel electrode included in the pixel electrode layer 12. Therefore, the flatness of the interlayer insulating film 8 directly under the pixel electrode can be improved. Thus the display quality can be improved.

Moreover, a protection circuit 123 formed in the frame area 112 over the TFT substrate 110 of the display device is explained with reference to FIG. 2B. The protection circuit 123 includes a first semiconductor device and a second semiconductor device. These semiconductor devices are rectifying device which each resistance value changes nonlinearly. For example, the first semiconductor device is a n-type transistor (n-Tr) and another second semiconductor device is a p type transistor (p-Tr) with a different conductivity type. This conductivity type may be opposite and is made according to the ion species at the time of filling impurities into the source/drain region 7, specifically. Note that the effect is the same even if it the first and the second semiconductor devices are replaced as appropriate.

A gate electrode and a drain electrode of the first semiconductor device are connected to a first short ring (not shown) and a source electrode is connected to the source line 153 or the gate line 182. That is, the first semiconductor device is made up of 2 terminal devices in which a gate of the TFT 120 is connected to a source or a drain of the TFT 120. Moreover, a gate electrode and a drain electrode of the second semiconductor device are connected to a second short ring (not shown) and a source electrode is connected to the source line 153 or the gate line 182. That is, the second semiconductor device is made up of 2 terminal devices in which a gate of the TFT 120 is connected to a source or a drain of the TFT 120. Note that for example, the first semiconductor device and the second semiconductor device are connected in parallel. The first semiconductor device is connected to the first short ring and the second semiconductor device is connected to the second short ring.

Then, corresponding to the case where a potential difference is generated between these short rings, one of the first semiconductor device and the second semiconductor device opens to be the same potential instantaneously. Here, “open” means that either the first semiconductor device or the second semiconductor device is set to ON and a potential difference is cleared when a charge flows through the semiconductor device being set to ON. In FIG. 2B, the case where the signal line 9 and the pixel electrode 12 are made to be the same potential is shown. For example, when the potential of the signal line 9 is higher than the potential of the pixel electrode 12, pTr turns on and an electron hole which is a carrier moves to the pixel electrode 12 from the signal line 9. On the other hand, when the potential of the signal line 9 is lower than the potential of the pixel electrode 12, nTr turns on and the electron which is a carrier moves to the signal line 9 from the pixel electrode 12. Furthermore, for example, if the pixel electrode layer 12 is connected to the gate electrode 15, the signal line 9 and the gate electrode 15 are connected through the semiconductor device being set to ON, and the potential difference of the signal line 9 and the gate electrode 15 can be cleared. As mentioned above, by combining semiconductor devices with different conductivity types, it is possible to discharge the static electricity accumulated in the source line 153 and the gate line 182 or the like via the first short ring or the second short ring. Note that the protection circuit 123 is formed in the frame area 112 of the TFT substrate 110 and prevents dielectric breakdown between the first conductive layer and the second conductive layer. This protects the source line 153 and the gate line 182.

The formation method of the protection circuit 123 is the same as that of the TFT part and the conversion part of the abovementioned display device. However, as shown in FIG. 2A, after forming the protective film 10, the contact hole 11 which penetrates the protective film 10 and the interlayer insulating film 8 to reach the gate electrode 15 is formed. Moreover, in this process, the contact hole 11 which penetrates the protective film 10, the interlayer insulating film 8 and the gate insulating film 5 to reach the polysilicon film 4 is formed. Then, the pixel electrode layer 12 is formed over the protective film 10. The pixel electrode layer 12 is laid under the contact hole 11. Then, in the protection circuit 123 formed in the frame area 112 of the TFT substrate 110, the polysilicon film 4 and the gate electrode 15 are physically and electrically connected via the pixel electrode layer 12 laid under the contact hole 11.

The TFT substrate formed as described above is bonded with an opposing substrate having an opposing electrode and a liquid crystal is filled between them. A sheet-like light source device which is a backlight unit is placed in the back side to manufacture a liquid crystal display. Moreover, in this embodiment, it is not limited to a liquid crystal display and can be incorporated to display devices such as an organic EL display and various electronic equipment at large.

### Second Embodiment

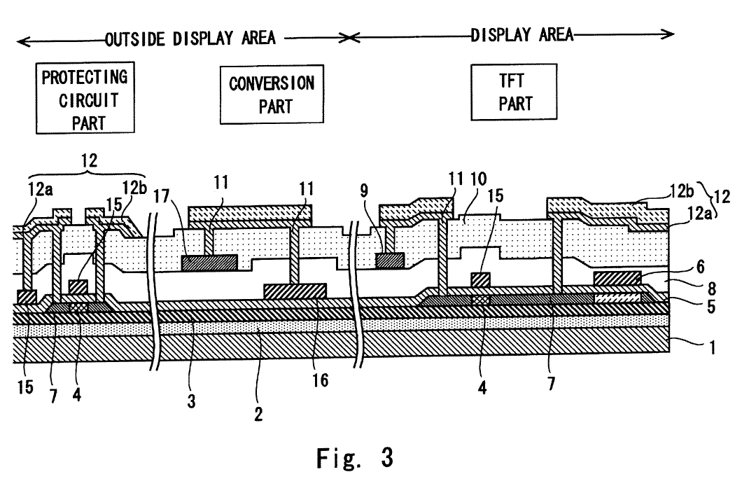

A TFT substrate according to a second embodiment of the present invention is explained with reference to FIG. 3. FIG. 3 is a cross-sectional diagram showing the TFT substrate according to this embodiment. In this embodiment, a different point from the first embodiment is only the structure of the pixel electrode layer 12, thus the detailed explanation is omitted.

FIG. 3 shows the structure in which the pixel electrode is formed with the conducting film of more than two layers. The pixel electrode layer 12 has a transparent conducting film such as an ITO film and a metallic film including metals such as Cr, Mo, Al, Ta and Ti, or using these metals as the main constituent. That is, in this embodiment, the pixel electrode layer 12 is the laminated structure having a lower layer conducting film 12a and an upper conductive layer 12b. Here, the upper conductive layer 12b is formed with an alloy which uses metal or metal as the main constituent and the lower layer conducting film 12a is formed with a transparent conducting film. As with the first embodiment, this enables to improve productivity and display quality. Furthermore, by having the laminated structure, resistance of the pixel electrode layer 12 between the first routing line 16 and the second routing line 17, and the polysilicon film 4 and the signal line 9 can be reduced. Thus display quality can be improved. By the laminated structure of the pixel electrode layer 12, a transflective LCD can be formed, for example. That is, in a pixel, a pixel electrode is formed only with a transparent conducting film in a transparent part and a pixel electrode is formed with a metal or an alloy in a reflective part.

Moreover, in the second embodiment, it is explained that the structure where the upper conductive layer 12b is a metal or an alloy using metal as the main constituent and the lower layer conducting film 12a is a transparent conducting film. However it may be the opposite structure. That is, the upper conductive layer 12b may be a transparent conducting film and the lower conductive layer may be a metal or an alloy using metal as the main constituent. Furthermore, this metal may be a high melting point metal such as Cr, Mo, Ta and Ti. By having such structure, further advantageous effects can be produced in addition to the abovementioned productivity improvement and resistance reduction. Hereinafter, the advantage effects are explained in detail.

In general, in the structure where the ITO used for the pixel electrode layer and the semiconductor thin film such as a polysilicon film are directly made to be in contact, an ITO which is a n-type semiconductor substantially and the semiconductor thin film are made to be in contact. Thus it is an non-ohmic contact and there is a problem that contact resistance indicates a high resistance value. Therefore, the abovementioned structure can be incorporated only to the portion where the influence of device performance is small, for example like a pixel contact part. Here, by intervening metals such as Cr, Mo, Ta and Ti between the ITO and the semiconductor thin film as mentioned above, the structure of ITO/metal/semiconductor thin film which is a transparent conducting film can be obtained. Then, the advantageous effect of an ohmic contact and a contact resistance with lower resistance can be obtained between the ITO and the semiconductor thin film. That is, it is possible to achieve the advantageous effect of reducing the contact resistance between the pixel electrode layer 12 and the polysilicon film 4.

### Third Embodiment

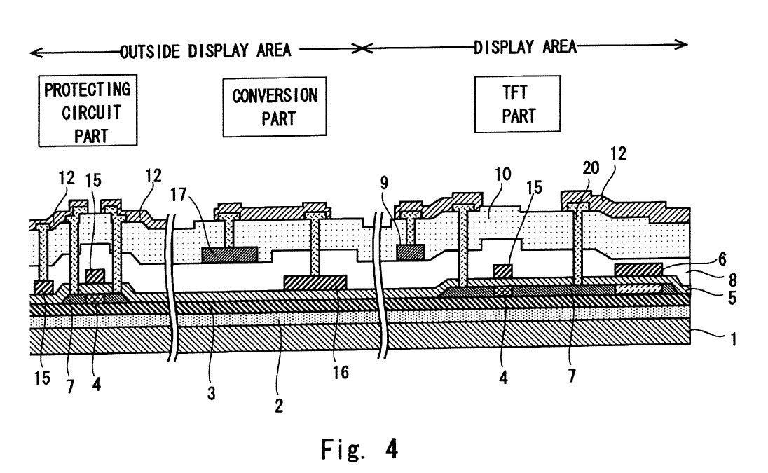

A TFT substrate according to a third embodiment of the present invention is explained with reference to FIG. 4. FIG. 4 is a cross-sectional diagram showing the TFT substrate according to this embodiment. In this embodiment, a different point from the first embodiment is that a barrier metal 20 is formed in the contact hole 11 when the pixel electrode uses a transparent conducting film such as ITO. Therefore, the explanation is omitted for the contents common in the first embodiment. Moreover, for the barrier metal 20, although it is also effective in reducing the contact resistance of the ITO and the semiconductor thin film also in the third embodiment as with the metal of the second embodiment, the explanation is omitted for this. Here, the barrier metal 20 is laid under the contact hole 11, for example. Therefore, the pixel electrode layer 12 and the source drain region 7 of the polysilicon film 4 are connected via the barrier metal 20. Moreover, the pixel electrode layer 12 and the first routing line 16 are connected via the barrier metal 20. Furthermore, the pixel electrode layer 12, the signal line 9 and the second routing line 17 are connected via the barrier metal 20. In this case, by forming the barrier metal 20, contact resistance of the ITO, the signal line layer which is a lower layer, the gate layer or the polysilicon film 4 can be reduced.

Note that this embodiment may be combined with the second embodiment. Furthermore, the barrier metal 20 is formed after opening the contact hole 11 followed by the formation of the protective film 10. For the barrier metal 20, Mo, Ti, Cr, W, etc. can be used. Moreover, in FIG. 4, although the barrier metal 20 connected to the signal line 9 is separated from the barrier metal 20 connected to the source/drain region 7, the signal line 9 and the source/drain region 7 may be connected via the barrier metal 20 by patterning so that they may be connected after forming the barrier metal 20. Thus, connection resistance decreases and the characteristics can be improved. Same applies between the first routing line 16 and the second routing line 17.

### Fourth Embodiment

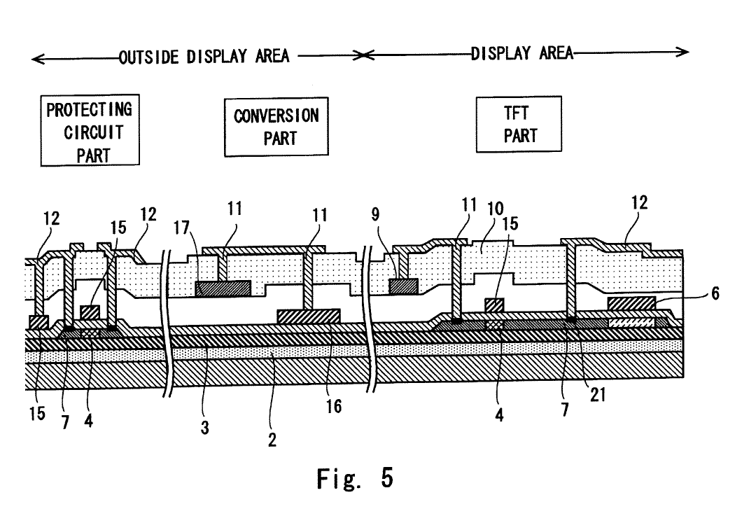

A TFT substrate according to a fourth embodiment of the present invention is explained with reference to FIG. 5. FIG. 5 is a cross-sectional diagram showing the TFT substrate according to this embodiment. In this embodiment, a different point from the first embodiment is to form a silicide 21 in at least the contact portion of the pixel electrode layer 12 and the polysilicon film 4 before forming the pixel electrode. Therefore, the explanation is omitted for the contents common in the first embodiment.

The silicide 21 is formed to the surface of the source/drain region 7 of the polysilicon film 4. Here, it is assumed that the pixel electrode layer 12 is formed by a transparent conducting film such as ITO. Or it is assumed that the lower conducting film of the pixel electrode layer 12 is formed with a transparent conducting film. In this case, the pixel electrode layer 12 and the source/drain region 7 of the polysilicon film 4 are connected via the silicide 21. Therefore, connection resistance can be reduced and display quality can be improved further.

### Fifth Embodiment

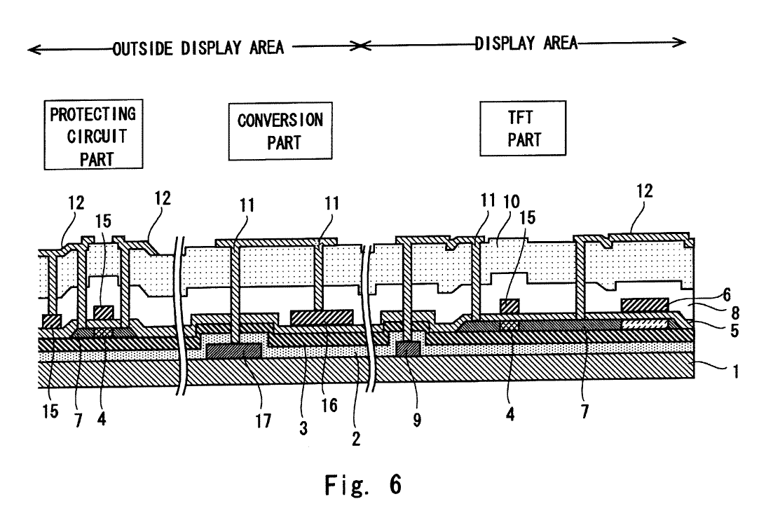

A TFT substrate according to a fifth embodiment of the present invention is explained with reference to FIG. 6. FIG. 6 is a cross-sectional diagram showing the TFT substrate according to this embodiment. In this embodiment, a different point from the first embodiment is that the signal line 9 and the second routing line 17 are formed in a lower layer than the silicon nitride film 2 and the silicon oxide film 3 as a foundation film. Therefore, the explanation is omitted for the contents common in the first embodiment.

Under the silicon nitride film 2, the signal line 9 and the second routing line 17 are formed. Here, over the pattern of the signal line 9 and the second routing line 17, the contact holes 11 are formed in the silicon nitride film 2, the silicon oxide film 3, the gate insulating film 5, the interlayer insulating film 8 and the protective film 10. The signal line 9 and the second routing line 17 are connected with the pixel electrode layer 12 through the contact holes 11. The contact hole 11 which penetrates the silicon nitride film 2 and the silicon oxide film 3 to reach the signal line 9 and the second routing line 17 is formed after forming the protective film 10. Therefore, the contact holes 11 which penetrate the silicon nitride film 2, the silicon oxide film 3, the gate insulating film 5, the interlayer insulating film 8 and the protective film 10 are formed with one photomask.

Thus the same advantageous effect as the abovementioned embodiments can be obtained. Note that in this embodiment, the signal line 9 and the second routing line 17, the silicon nitride film 2 and the silicon oxide film 3 are formed sequentially over the glass substrate 1. Since the process of forming the silicon nitride film 2 is the same as that of the first embodiment, the explanation is omitted. Note that in this embodiment, the signal line 9 and the second routing line 17 are formed under the silicon nitride film 2. For this reason, there is no need for the process of forming the signal line 9 and the second routing line 17 between interlayer insulating film 8 formation process and the protective film 10 formation process. Moreover, materials other than the silicon nitride film 2 and the silicon oxide film 3 may be used for the foundation film and it may a single layer structure.

### Sixth Embodiment

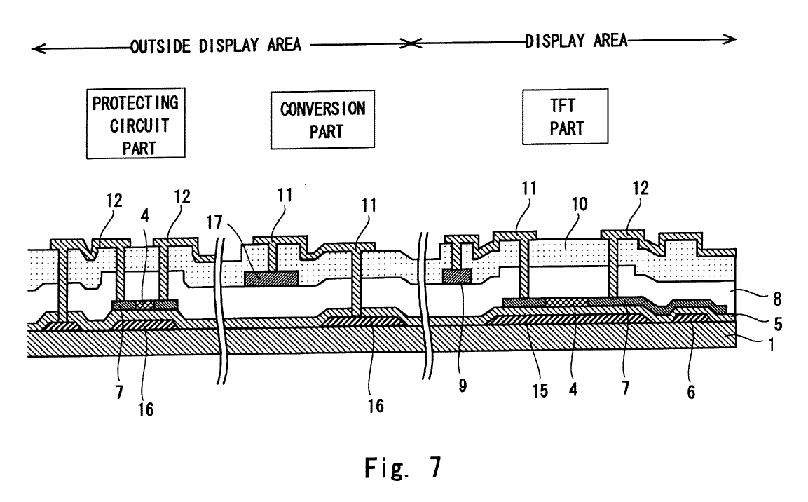

A TFT substrate according to a sixth embodiment of the present invention is explained with reference to FIG. 7. In FIG. 7, a bottom gate type TFT is formed to the TFT substrate. That is, the gate insulating film 5 is formed to the lower layer of the polysilicon film 4. Furthermore, the gate electrode 15, the capacitor electrode 6, and the first routing line 16 are formed to the lower layer of the gate insulating film 5. Then, the gate electrode 15 is disposed under the polysilicon film 4. In this case, over the glass substrate 1, the gate electrode 15, the gate insulating film 5 and the polysilicon film 4 are formed in this order. Note that for the formation process after forming the polysilicon film 4 is the same as that of the first embodiment, thus the explanation is omitted.

### Seventh Embodiment

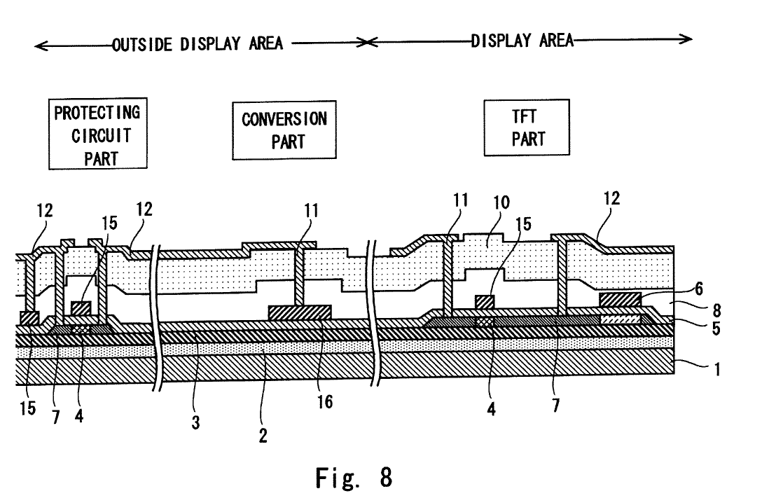

A TFT substrate according to a seventh embodiment of the present invention is explained with reference to FIG. 8. The structure in the seventh embodiment is that the signal line 9 and the second routing line 17 are not formed. That is, after forming the interlayer insulating film 8, the signal line 9 and the second routing line 17 are not formed before forming the protective film 10 or the silicon nitride film 2. Therefore, the signal line 9 and the second routing line 17 are not disposed between the interlayer insulating film 8 and the protective film 10 and under the silicon nitride film 2. In this process, as the formation process of the signal line 9 and the second routing line 17 can be skipped, productivity can be improved further.

### Eighth Embodiment

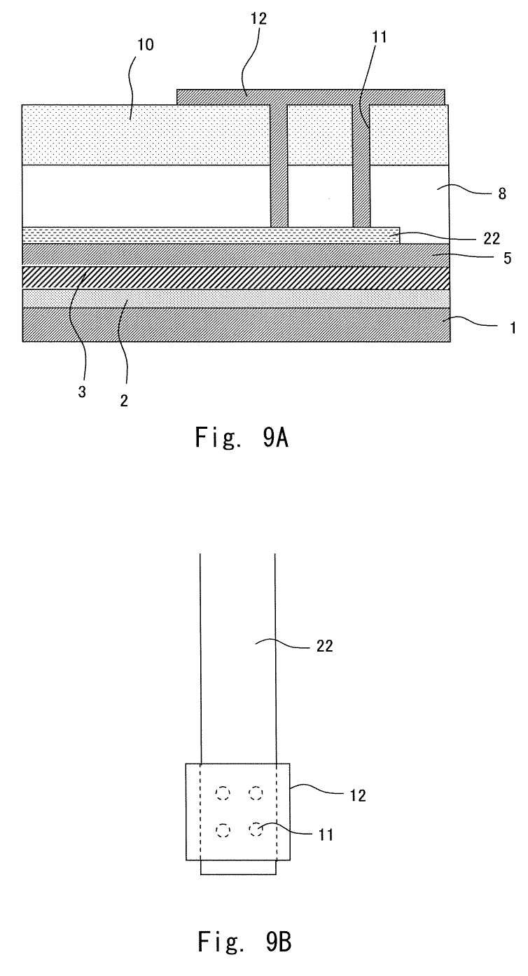

A TFT substrate according to an eighth embodiment of the present invention is explained with reference to FIGS. 9A and 9B. In the eighth embodiment, the structure of the terminal area formed in the frame area 112 of the substrate 110 shown in FIG. 1 and connected with a pad of the scanning signal drive circuit 115 or the display signal drive circuit 116 is explained. Here, FIG. 9A is a cross-sectional diagram showing the terminal area of the TFT substrate according to the eighth embodiment. Moreover, FIG. 9B is a plan view showing the terminal area of the TFT substrate according to the eighth embodiment. Here, the structure of one terminal area is shown among a plurality of terminal areas. Moreover, in the eighth embodiment shown in FIGS. 9A and 9B, the explanation is omitted concerning the same component as the first embodiment.

As shown in FIG. 9A, the silicon nitride film 2 and the silicon oxide film 3 to be the foundation film is formed by plasma CVD method over the glass substrate 1. Next, although the polysilicon film 4 to be the semiconductor layer is formed in the TFT 120, this polysilicon film 4 is removed by etching in the terminal area according to the eighth embodiment. Then, over the silicon oxide film 3, the gate insulating film 5 is formed by plasma CVD method. Subsequently, a metal thin film to be a terminal wiring 22 is formed by sputtering method using Al, Cr, Mo, Ti, W etc. or an alloy of these metals added with a small amount of other material. Over this metal thin film, a resist pattern is formed by photolithography. Then, the metal thin film is patterned in a desired shape with an etchant to remove the resist over the metal thin film. The terminal wiring 22 is formed in this way. Here, in the TFT 120, the gate electrode 15, the capacitor electrode 6 and the first routing line 16 are formed in the same layer as the terminal wiring 22. Moreover, impurities are introduced into the polysilicon film 4 formed over the silicon oxide film 3 by the gate electrode 15 and the capacitor electrode 6 as a mask.

A silicon oxide film to be the interlayer insulating film 8 is formed over the terminal wiring 22 by plasma CVD method. Then the terminal wiring 22 is covered with the interlayer insulating film 8. The interlayer insulating film 8 is a 500 nm thickness silicon oxide film to which TEOS and O₂ were made to react. Note that the film thickness of the interlayer insulating film 8 is set to 500 nm, however it is not limited to this. Furthermore, the interlayer insulating film 8 is not limited to a silicon oxide film but may be a silicon nitride film or an organic film etc.

Here, in the TFT 120, in order to activate P (phosphorus) and B (boron) which were introduced into the polysilicon film 4, a heat treatment is performed. Subsequently, the signal line 9 made up of a source drain metal is formed by sputtering in the TFT 120 and the second routing line 17 is formed in the conversion part, however in this embodiment which is the structure of the terminal area, the signal line 9 is not formed.

Next, 300 nm of a silicon nitride film to be the protective film 10 is formed by plasma CVD method over the interlayer insulating film 8. This protective film 10 is disposed above the terminal wiring 22. Moreover, the protective film 10 is not limited to a silicon nitride film but may be an insulating film such as a silicon oxide film and an organic film. Here, a heat treatment is performed for damage recovery of the polysilicon film 4 in the TFT 120.

After forming the protective film 10, the contact hole 11 which penetrates the protective film 10 and the interlayer insulating film 8 to reach the terminal wiring 22 is formed. At this time, in the conversion part, the contact hole 11 which penetrates the protective film 10 and the interlayer insulating film 8 to reach the first routing line 16 is formed. Furthermore, in the TFT 120, the contact hole 11 which penetrates the protective film 10, the interlayer insulating film 8 and the gate insulating film 5 to reach the source/drain region 7 of the polysilicon film 4 is formed. Specifically, a resist pattern is formed over the protective film 10 by photolithography method. Then, the protective film 10, the interlayer insulating film 8 and the gate insulating film 5 are dry etched in turn. The contact holes 11 are formed in this way. With one photomask, the contact holes 11 which penetrate the protective film 10, the interlayer insulating film 8 and the gate insulating film 5 can be formed. Here, four contact holes 11 are formed in one terminal area.

After forming the contact holes 11, the pixel electrode layer 12 is formed. Then, the pixel electrode layer 12 is patterned by photolithography method etc. The pixel electrode layer 12 can be formed with a transparent conducting film such as an ITO film. Or the pixel electrode layer 12 may be formed with metals such as Cr, Mo, Al, Ta and Ti or an alloy which uses these metals as the main constituent. This pixel electrode layer 12 can be formed with a transparent conducting film such as an ITO film. Or it is also possible to form the pixel electrode layer with metals such as Cr, Mo, Al, Ta and Ti or an alloy which uses these metals as the main constituent. This pixel electrode layer 12 is laid under the contact hole 11. Accordingly, the terminal wiring 22 and the pixel electrode layer 12 are physically and electrically connected. At this time, in the TFT 120, a pixel electrode or the like applied with a driving voltage (display voltage) for driving a liquid crystal is formed.

In the eighth embodiment, the terminal wiring 22 and the pixel electrode layer 12 can be connected by one contact hole formation. That is, in a related art, there was a formation process of the contact holes 11 for each of the interlayer insulating film 8 and the protective film 10 and each contact hole was formed in a different position over a substrate surface. On the other hand, the contact holes 11 formed in each of the interlayer insulating film 8 and the protective film 10 are formed collectively in this embodiment. Therefore, the area to dispose the contact holes 11 over the substrate surface can be reduced. Consequently, the area of the frame area 112 can be reduced.

### Ninth Embodiment

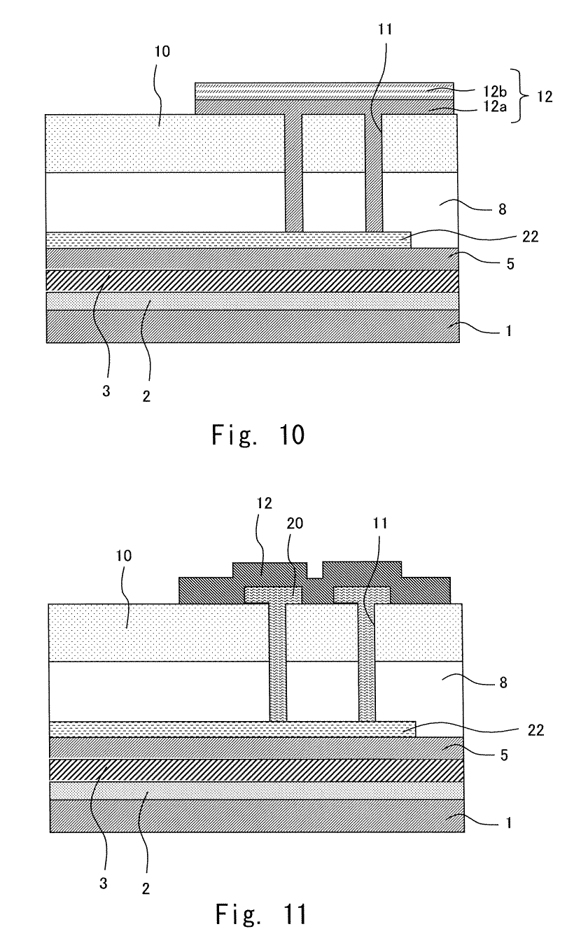

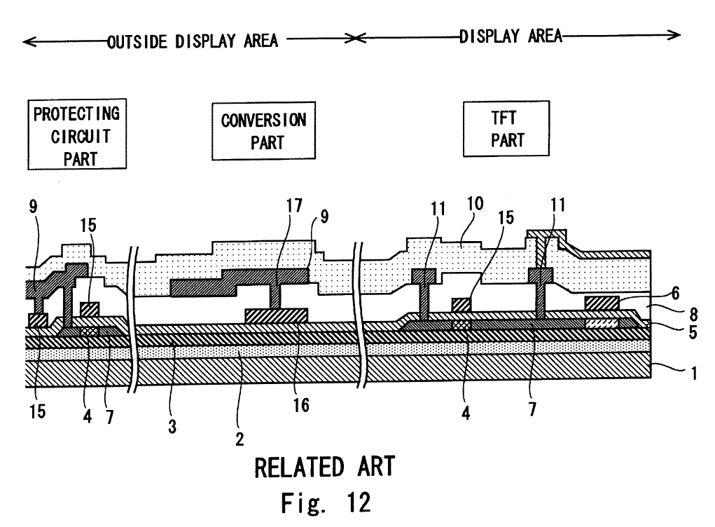

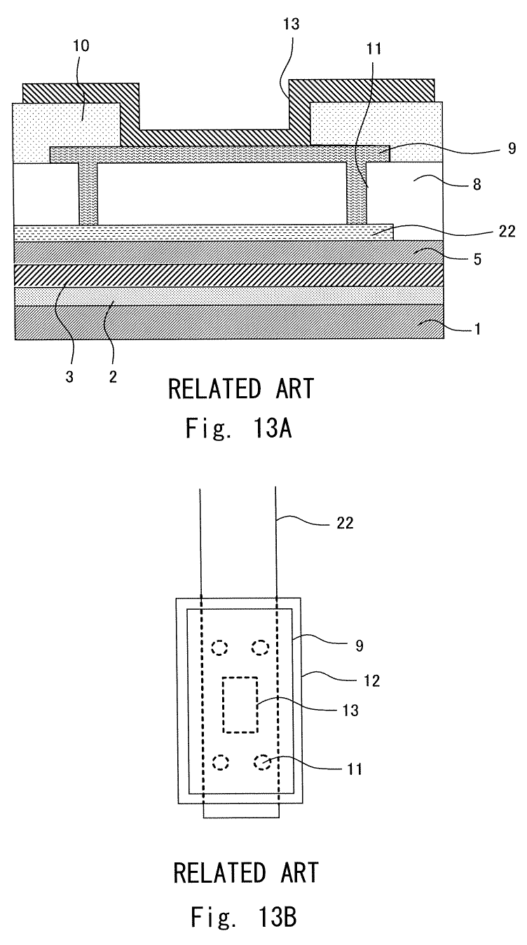

A TFT substrate according to a ninth embodiment of the present invention is explained with reference to FIG. 10. In the ninth embodiment, the structure of the terminal area formed over the same substrate as the TFT 120 shown in the second embodiment is described. FIG. 10 is a cross-sectional diagram showing the terminal area of the TFT substrate according to this embodiment. Moreover, in this embodiment, a different point from the terminal area shown in the eighth embodiment is only the structure of the pixel electrode layer 12. Thus the detailed explanation is omitted.

FIG. 10 shows the structure for forming the pixel electrode with the conducting film of more than two layers. The pixel electrode layer 12 has a transparent conducting film such as an ITO film and a metallic film including metals such as Cr, Mo, Al, Ta and Ti, or using these metals as the main constituent. That is, in this embodiment, the pixel electrode layer 12 is the laminated structure having the lower layer conducting film 12a and the upper conductive layer 12b. Here, the upper conductive layer 12b is formed with an alloy which uses metal or metal as the main constituent and the lower layer conducting film 12a is formed with a transparent conducting film. As with the first embodiment, this enables to improve productivity and display quality. The abovementioned structure is suitable for a transmissive liquid crystal display and a reflective liquid crystal display.

### Tenth Embodiment

A TFT substrate according to a tenth embodiment of the present invention is explained with reference to FIG. 11. In the tenth embodiment, the structure of the terminal area formed over the same substrate as the TFT 120 shown in third embodiment is described. FIG. 11 is a cross-sectional diagram showing the terminal area of the TFT substrate according to this embodiment. Moreover, in this embodiment, a different point from the eighth embodiment is to form the barrier metal 20 in the contact hole 11 in case of that the pixel electrode is an transparent conducting film such as ITO. Therefore, the explanation is omitted for the contents common in the eighth embodiment.

Here, the barrier metal 20 is laid under the contact hole 11, for example. Therefore, the terminal wiring 22 is connected with the pixel electrode layer 12 via the barrier metal 20. In this case, by forming the barrier metal 20, contact resistance of the ITO and the signal line layer, the gate layer or the polysilicon film 4 can be reduced, for example. The signal layer, the gate layer, and the polysilicon film 4 are formed in a lower layer of the ITO. Moreover, in the conversion part, contact resistance of the ITO and the signal line layer, the gate layer or the polysilicon film 4 can be reduced. The signal layer, the gate layer, and the polysilicon film 14 are formed in a lower layer of the ITO. Therefore, display quality can be improved further.

Note that this embodiment may be combined with the ninth embodiment. Moreover, the barrier metal 20 is formed after opening the contact hole 11 followed by the formation of the protective film 10. For the barrier metal 20, Mo, Ti, Cr, W, etc. can be used.

### Eleventh Embodiment

A TFT substrate according to a eleventh embodiment of the present invention is explained. In the eleventh embodiment, the structure of the terminal area formed over the same substrate as the TFT 120 shown in fourth embodiment is described. In this embodiment, a different point from the eighth embodiment is to form the silicide 21 in at least the contact portion of the pixel electrode layer 12 and the polysilicon film 4 before forming the pixel electrode in the TFT 120. Therefore, as the terminal area has the same structure as the eighth embodiment, the detailed explanation is omitted. That is, in the eleventh embodiment, the TFT 120 shown in the fourth embodiment and the terminal area shown in the eighth embodiment are included.

### Twelfth Embodiment

A TFT substrate according to a twelfth embodiment of the present invention is explained. In the twelfth embodiment, the structure of the terminal area formed over the same substrate as the TFT 120 shown in fifth embodiment is described. In this embodiment, a different point from eighth embodiment is that the signal line 9 and the second routing line 17 are formed in a lower layer than the silicon nitride film 2 and the silicon oxide film 3 as a foundation film. Therefore, as the terminal area has the same structure as the eighth embodiment, the detailed explanation is omitted. That is, in the twelfth embodiment, the TFT 120 shown in the third embodiment and the terminal area shown in the eighth embodiment are included.

As for the TFT substrate formed by the manufacturing method of the abovementioned embodiment, the contact holes can be formed in one process and the number of mask process can be reduced by at least one. In this case, the contact hole is not formed under the signal line, but the flatness of the topmost surface of the pixel electrode improves. Note that in the first to the twelfth embodiments, the capacitor electrode 6 is formed in the same conductive layer as the gate electrode 15, however it may be formed in the same layer as the signal line 9. Furthermore, the first to the twelfth embodiments may be combined as appropriate.

The TFT array substrate illustrated in the first to twelfth embodiments of the present invention has high productivity and is suitable for a display device. More specifically, the TFT array substrate can be used to a display device equipped with an active matrix array display having signal lines and scanning lines crossing each other in a display area of the display device and TFTs disposed near the intersections.

For example, it is possible to incorporate to a liquid crystal display formed by bonding an array substrate and a color filter together with a seal material interposed therebetween and filling a liquid crystal material inside. Moreover, not only to a display area but the TFT array substrate may be incorporated to a TFT of a drive circuit located around the display area. In such case, it can be formed simultaneously with the TFT in the display area.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A display device comprising:
a substrate;
a gate insulating film provided over the substrate and disposed between a semiconductor layer and a first conductive layer including a capacitor electrode and a gate electrode;
an interlayer insulating film formed over the semiconductor layer, the first conductive layer and the gate insulating film;
a second conductive layer having a signal line formed over the interlayer insulating film;
a protective film formed over the interlayer insulating film and the second conductive layer; and
a pixel electrode layer formed over the protective film,
wherein the semiconductor layer and the second conductive layer are connected via the pixel electrode layer by the pixel electrode layer penetrating the protective film to reach the second conductive layer and also penetrating the protective film, the interlayer insulating film and the gate insulating film to reach the semiconductor layer.

2. The display device according to claim 1, wherein the first conductive layer and the second conductive layer are connected via the pixel electrode layer by the pixel electrode layer penetrating the protective film to reach the second conductive layer and also penetrating the protective film and the interlayer insulating film to reach the first conductive layer.

3. The display device according to claim 1, wherein the first conductive layer and the semiconductor layer are connected via the pixel electrode layer by the pixel electrode layer penetrating the protective film and the interlayer insulating film to reach the first conductive layer and also penetrating the protective film, the interlayer insulating film and the gate insulating film to reach the semiconductor layer.

4. The display device according to claim 2, further comprising:
a gate line and a source line formed in a display area over the substrate;
a driving circuit for supplying a signal to the gate line or the source line; and
a first routing line or a second routing line formed in a frame area outside the display area over the substrate for connecting the driving circuit with the gate line and the source line,
wherein the first conductive layer includes the first routing line,
the second conductive line includes the second routing line, and
the first routing line and the second routing line are connected via the pixel electrode layer by the pixel electrode layer penetrating the protective film to reach the second routing line and also penetrating the protective film and the interlayer insulating film to reach the first routing line.

5. The display device according to claim 3, further comprising:
a gate line and a source line formed in a display area over the substrate;
a driving circuit for supplying a signal to the gate line or the source line;
a first routing line or a second routing line formed in a frame area outside the display area over the substrate for connecting the driving circuit with the gate line and the source line; and
a protection circuit formed outside the display area over the substrate for protecting each line from dielectric breakdown between the gate line and the source line or dielectric breakdown between the first routing line and the second routing line,
wherein in the protection circuit, the gate electrode and the semiconductor layer are connected via the pixel electrode layer by the pixel electrode layer penetrating the protective film and the interlayer insulating film to reach the gate electrode and also penetrating the protective film, the interlayer insulating film and the gate insulating film to reach the semiconductor layer.

6. The display device according to claim 1, wherein in all areas provided with the second conductive layer, a contact hole is not formed directly under the second conductive layer.

7. The display device according to claim 1, further comprising a contact hole reaching the semiconductor layer and a contact hole reaching the second conductive layer formed in one etching process.

8. The display device according to claim 1, further comprising a contact hole reaching the semiconductor layer, a contact hole reaching the first conductive layer and a contact hole reaching the second conductive layer formed in one etching process.

9. The display device according to claim 1, wherein the pixel electrode layer includes a transparent conductive layer.

10. The display device according to claim 9, wherein the pixel electrode layer and the semiconductor layer are connected via a barrier metal.

11. The display device according to claim 1, wherein the pixel electrode layer includes metal or an alloy using metal as main constituent.

12. The display device according to claim 1, wherein the pixel electrode layer is a laminated structure having an upper conducting film and a lower conducting film.

13. The display device according to claim 1, further comprising a terminal wiring provided outside a display area over the substrate and formed under the interlayer insulating film,
wherein the terminal wiring and the pixel electrode layer are connected by the pixel electrode layer penetrating the protective film and the interlayer insulating film to reach the terminal wiring.

14. A method of manufacturing a display device comprising:
forming a semiconductor layer, a first conductive layer including a capacitor electrode and a gate electrode and a gate insulating film disposed between the semiconductor layer and the first conductive layer over a substrate;
forming an interlayer insulating film over the semiconductor layer, the first conductive layer and the gate insulating film;
forming a second conductive layer having a signal line over the interlayer insulating film;
forming a protective film over the interlayer insulating film and the second conductive layer;
forming a contact hole penetrating the protective film to reach the second conductive layer, a contact hole penetrating the protective film and the interlayer insulating film to reach the first conductive layer and a contact hole penetrating the protective film, the interlayer insulating film and the gate insulating film to reach the semiconductor layer after forming the protective film; and
forming a pixel electrode layer over the protective film after forming the contact holes.

15. The method according to claim 14, wherein the contact hole reaching the semiconductor layer and the contact hole reaching the second conductive layer are formed in one etching process.

16. The method according to claim 14, wherein the contact hole reaching the semiconductor layer, the contact hole reaching the first conductive layer and the contact hole reaching the second conductive layer are formed in one etching process.

17. The method according to claim 14, wherein in the formation of the semiconductor layer, the first conductive layer and the gate insulating film over the substrate, a terminal wiring is formed outside a display area over the substrate, and
in the formation of the contact holes, a contact hole reaching the terminal wiring is formed.

18. The method according to claim 17, wherein the contact hole reaching the second conductive layer and the contact hole reaching the terminal wiring are formed in one etching process.
